(19) United States
(12) Patent Application Publication
(10) Pub. No.: US 2026/0011650 A1
(43) Pub. Date: Jan. 8, 2026

(54) SEMICONDUCTOR PACKAGE

(71) Applicant: Samsung Electronics Co., Ltd., Suwon-si (KR)

(72) Inventors: Jinwon CHAE, Suwon-si (KR); Inwook JUNG, Suwon-si (KR); Sukhyun KIM, Suwon-si (KR)

(73) Assignee: Samsung Electronics Co., Ltd., Suwon-si (KR)

(21) Appl. No.: 19/073,652

(22) Filed: Mar. 7, 2025

(30) Foreign Application Priority Data
Jul. 8, 2024 (KR) 10-2024-0089373

(51) Int. Cl. H01L 23/538; H01L 23/00; H01L 23/31; H01L 23/367; H01L 25/16; H10B 80/00

(52) U.S. Cl. CPC H01L 23/5385; H01L 23/3135; H01L 23/5386; H01L 25/16; H01L 23/3675; H01L 24/16; H01L 24/32; H01L 24/73; H01L 2224/16227; H01L 2224/32225; H01L 2224/73204; H10B 80/00

(57) ABSTRACT

A semiconductor package may include an interposer substrate having first and second surfaces, a through electrode extending through the interposer substrate, an RDL on the first surface of the interposer substrate and an upper surface of the through electrode and including a redistribution wiring structure, first and second semiconductor chips electrically connected to the redistribution wiring structure on the RDL, a first molding member on the RDL and covering sidewalls of the first and second semiconductor chips, a conductive post on the second surface of the interposer substrate and contacting the through electrode, and a second molding member on the second surface of the interposer substrate and covering a sidewall of the conductive post. A maximum width of the through electrode is equal to or greater than that of the conductive post. A length of the through electrode is equal to or less than that of the conductive post.

### CROSS-REFERENCE TO RELATED APPLICATION

This application claims priority under 35 U.S.C. § 119 to Korean Patent Application No. 10-2024-0089373, filed on Jul. 8, 2024 in the Korean Intellectual Property Office (KIPO), the contents of which are herein incorporated by reference in their entirety.

### BACKGROUND

### 1. Field

At least some example embodiments relate to a semiconductor package. For example, at least some example embodiments may relate to a multi-chip package including a plurality of stacked chips.

### 2. Description of the Related Art

When a semiconductor package including an interposer is manufactured, a grinding process for exposing a through electrode in the interposer, and/or a thermal compression bonding (TCB) process for bonding semiconductor chips onto a redistribution layer (RDL) in the interposer, may be performed. During the grinding process and/or the TCB process, many carrier substrates may be used, which may complicate the processes and increase the cost of the processes.

### SUMMARY

Some example embodiments relate to a semiconductor package having enhanced electrical characteristics.

According to some example embodiments, a semiconductor package may include an interposer substrate having first and second surfaces opposite to each other in a vertical direction, a through electrode at least partially extending through the interposer substrate, a redistribution layer (RDL) on the first surface of the interposer substrate and on an upper surface of the through electrode and including a redistribution wiring structure, first and second semiconductor chips, each of which may be electrically connected to the redistribution wiring structure, on the RDL and spaced apart from each other in a horizontal direction, a first molding member on the RDL and at least partially covering a sidewall of the first and a side wall of the second semiconductor chip, a conductive post on the second surface of the interposer substrate and contacting the through electrode, and a second molding member on the second surface of the interposer substrate and at least partially covering a sidewall of the conductive post. A maximum width in the horizontal direction of the through electrode may be equal to or greater than a width in the horizontal direction of the conductive post. A length in the vertical direction of the through electrode may be equal to or less than a length in the vertical direction of the conductive post.

According to example embodiments, there is provided a semiconductor package may include an interposer substrate having first and second surfaces opposite to each other in a vertical direction, a through electrode at least partially extending through the interposer substrate, a redistribution layer (RDL) on the first surface of the interposer substrate and on an upper surface of the through electrode and including a redistribution wiring structure, first and second semiconductor chips, each of which may be electrically connected to the redistribution wiring structure, spaced apart from each other in a horizontal direction on the RDL, a first molding member on the RDL and at least partially covering a sidewall of the first semiconductor chip and a sidewall of the second semiconductor chip, a conductive post on the second surface of the interposer substrate and contacting the through electrode, a third semiconductor chip spaced apart from the conductive post in the horizontal direction and under the second surface of the interposer substrate and at least partially overlapping with each of the first and second semiconductor chips in the vertical direction, and a second molding member on the second surface of the interposer substrate and at least partially covering a sidewall of the conductive post and the third semiconductor chip.

According to some example embodiments, a semiconductor package may include an interposer substrate having first and second surfaces opposite to each other in a vertical direction, through electrodes, each of which may at least partially extend through the interposer substrate, spaced apart from each other in a horizontal direction, a redistribution layer (RDL) on the first surface of the interposer substrate and upper surfaces of the through electrodes and including a redistribution wiring structure, conductive pads on the RDL and spaced apart from each other in the horizontal direction, a first conductive connection member contacting an upper surface of a first conductive pad among the conductive pads, a first semiconductor chip on and electrically connected to the first conductive connection member, a first underfill member between the RDL and the first semiconductor chip and at least partially covering the first conductive pad and the first conductive connection member, a second conductive connection member contacting an upper surface of a second conductive pad among the conductive pads, a second semiconductor chip on and electronically connected to the second conductive connection member, a second underfill member between the RDL and the second semiconductor chip and covering the second conductive pad and the second conductive connection member, a first molding member on the RDL and at least at least partially covering a sidewall of the first semiconductor chip, a sidewall of the second semiconductor chip, a sidewall of the first underfill member, and a sidewall of second underfill member, conductive posts on the second surface of the interposer substrate and contacting the through electrodes, respectively, and a second molding member on the second surface of the interposer substrate and a least partially covering a sidewall of the conductive posts. A maximum width in the horizontal direction of each of the through electrodes may be equal to or greater than a width in the horizontal direction of a corresponding one of the conductive posts.

In the method of manufacturing the semiconductor package in accordance with example embodiments, each of the through electrodes in the interposer substrate may have a relatively small length, the number of using carrier substrates may be relatively reduced, and the molding members including a same coefficient of thermal expansion (CTE) may be formed on and beneath the interposer substrate so as to prevent or reduce warpage of the interposer substrate.

Additionally, a portion of the interposer substrate and some of the through electrodes extending through the interposer substrate may be replaced with the molding member and the conductive posts, and an additional semiconductor chip may be disposed between the conductive posts, so that the semiconductor package may have enhanced electrical characteristics.

### BRIEF DESCRIPTION OF THE DRAWINGS

FIG. 1 is a cross-sectional view illustrating a semiconductor package in accordance with some example embodiments, and FIG. 2 is an enlarged cross-sectional view of a region X of FIG. 1.

FIGS. 3 to 11 are cross-sectional views illustrating methods of manufacturing a semiconductor package in accordance with example embodiments.

FIGS. 12 and 13 are cross-sectional views illustrating semiconductor packages in accordance with example embodiments.

FIG. 14 is a cross-sectional view illustrating a semiconductor module in accordance with example embodiments.

### DETAILED DESCRIPTION OF EXAMPLE EMBODIMENTS

Hereinafter, some example embodiments will be explained in detail with reference to the accompanying drawings. Hereinafter, a direction parallel or substantially parallel to, for example, an upper surface of a wafer, a substrate or an interposer may be referred to as a horizontal direction, and a direction perpendicular to or substantially perpendicular to, for example, the upper surface of the wafer, the substrate or the interposer may be referred to as a vertical direction.

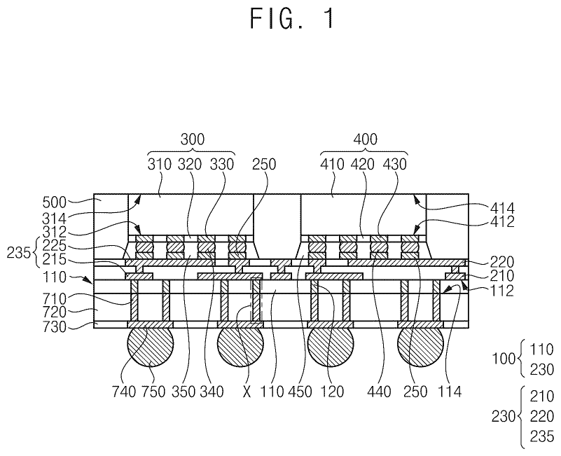

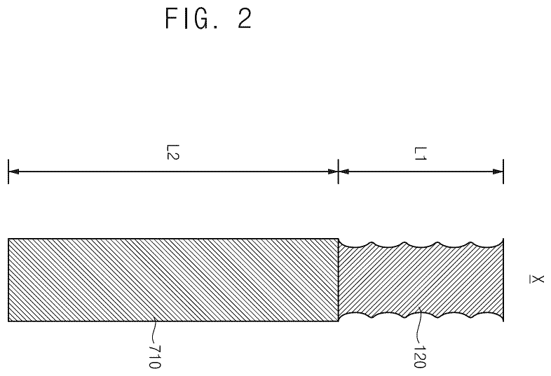

FIG. 1 is a cross-sectional view illustrating a semiconductor package in accordance with example embodiments, and FIG. 2 is an enlarged cross-sectional view of a region X of FIG. 1.

Referring to FIGS. 1 and 2, the semiconductor package may include an interposer 100, first and second semiconductor chips 300 and 400 and a first molding member 500 disposed on the interposer 100, and a conductive post 710, a second molding member 720 and a third conductive connection member 750 disposed under the interposer 100.

The semiconductor package may further include second and fifth conductive pads 250 and 740, first and second conductive connection members 340 and 440, first and second underfill members 350 and 450, and a third insulation layer 730.

The interposer 100 may include an interposer substrate 110 having first and second surfaces 112 and 114 opposite to each other in the vertical direction, and a redistribution layer (RDL) 230 on the first surface 112 of the interposer substrate 110.

In some example embodiments, the interposer substrate 110 may include, e.g., a semiconductor material such as silicon, germanium, silicon-germanium, etc., or glass.

A plurality of first through electrodes 120, each of which may extend through the interposer substrate 110 in the vertical direction, may be spaced apart from each other in the horizontal direction in the interposer substrate 110. In some example embodiments, a cross-section of a sidewall of the first through electrode 120 in the vertical direction may not be flat but uneven, and may have, e.g., a scalloped, rippled, corrugated, or similar shape. In some example embodiments, the first through electrode 120 may have a first length L1 of about 30 μm to about 50 μm in the vertical direction, but example embodiments are not limited thereto.

Each of the first through electrodes 120 may include a metal, e.g., a copper, aluminum, etc., or a metal nitride, e.g., titanium nitride, tantalum nitride, etc., but example embodiments are not limited thereto.

In some example embodiments, the RDL 230 may include insulation layers stacked on the interposer substrate 110 in the vertical direction and a redistribution wiring structure in the insulation layers, and the redistribution wiring structure may include, e.g., redistribution wirings, vias, contact plugs, conductive pads, etc., but example embodiments are not limited thereto. FIG. 1 shows that the RDL 230 includes first and second insulation layers 210 and 220 stacked in the vertical direction, and the redistribution wiring structure 235 includes a first conductive pad 215 and a redistribution wiring 225. However, inventive concepts are not limited thereto, and the RDL 230 may include more than two insulation layers, and the redistribution wiring structure 235 may include redistribution wirings, vias, contact plugs, conductive pads, etc., having various vertical and horizontal layouts.

An upper surface of each of the first through electrodes 120 may contact a lower surface of the first conductive pad 215, and may be electrically connected thereto.

In some example embodiments, each of the first and second insulation layers 210 and 220 may include, for example, an organic insulation material. The organic insulation material may include, for example, a polymer, e.g., polyimide, but example embodiments are not limited thereto. Any of each of the first and second conductive pad 215 and 250 and the redistribution wiring 225 may include, e.g., aluminum, copper, tin, nickel, gold, platinum, etc., or any alloy thereof, but example embodiments are not limited thereto.

In some example embodiments, the conductive post 710, which may be under the second surface 114 of the interposer substrate 110, may contact a lower surface of the first through electrode 120. In some example embodiments, a plurality of conductive posts 710 may be spaced apart from each other in the horizontal direction according to layout of the first through electrodes 120.

In some example embodiments, the conductive post 710 may have a shape of a pillar extending in the vertical direction, and a cross-section of a sidewall of the conductive post 710 in the vertical direction may be flat or substantially flat. As the cross-section of the sidewall of the first through electrode 120, which may be disposed on the conductive post 710, may not be not flat but may have a different shape, e.g., a scalloped, rippled, corrugated, or similar shape, the conductive post 710 may be differentiated from the first through electrode 120 by the profile of the sidewall of the conductive post 710. In some example embodiments, a horizontal width of the conductive post 710 may be, for example, the same as, substantially the same as, or less than that of the first through electrode 120, but example embodiments are not limited thereto.

In some example embodiments, the conductive post 710 may have a second length L2 of, for example, about 50 μm to about 70 μm in the vertical direction. Accordingly, the second length L2 in the vertical direction of the conductive post 710 may be the same as, substantially the same as, or greater than the first length L1 in the vertical direction of the first through electrode 120. The second length L2 of the conductive post 710 may be, for example, about 1 to 2.5 times the first length L1 of the first through electrode 120, but example embodiments are not limited thereto.

The conductive post 710 may include, for example, a metal, e.g., copper, but example embodiments are not limited thereto.

The second molding member 720 may be disposed under the second surface 114 of the interposer substrate 110, and may cover or at least partially cover a sidewall of the conductive post 710. The second molding member 720 may include, for example, a polymer, e.g., an epoxy molding compound (EMC), but example embodiments are not limited thereto.

The third insulation layer 730 may be disposed under the second molding member 720 and under the conductive post 710, and may cover or at least partially cover a sidewall of the fifth conductive pad 740. In some example embodiments, a plurality of fifth conductive pads 740 may be spaced apart from each other in the horizontal direction. The third insulation layer 730 may include, for example, an insulating material, e.g., silicon oxide, and the fifth conductive pad 740 may include, e.g., a metal, a metal nitride, a metal silicide, etc., but example embodiments are not limited thereto.

Alternatively, an additional RDL, including a redistribution wiring structure, may be formed instead of the third insulation layer 730 and the fifth conductive pad 740.

The third conductive connection member 750 may contact a lower surface of the fifth conductive pad 740. In some example embodiments, a plurality of fifth conductive pads 740 may be spaced apart from each other in the horizontal direction.

The third conductive connection member 750 may include, e.g., a conductive bump and/or a conductive ball, and may include, for example, a metal, e.g., copper, aluminum, nickel, etc., or, for example, solder that is or includes, for example, an alloy of tin, silver, copper and/or lead, but example embodiments are not limited thereto. The third conductive connection member 750 may be, for example, mounted on a package substrate, e.g., a printed circuit board (PCB), a mother board, etc., to be electrically connected thereto, but example embodiments are not limited thereto.

The second conductive pad 250 may be disposed on the RDL 230, and may contact an upper surface of the redistribution wiring 225 in the redistribution wiring structure 235 as to be electrically connected thereto. In some example embodiments, a plurality of second conductive pads 250 may be spaced apart from each other in the horizontal direction.

The first conductive connection member 340 may be disposed on and contact an upper surface of a corresponding one of the second conductive pads 250. The first conductive connection member 340 may include, e.g., a conductive bump and/or a conductive ball, but example embodiments are not limited thereto.

In some example embodiments, the first semiconductor chip 300 may include, for example, an application-specific integrated circuit (ASIC) chip, e.g., a graphics processing unit (GPU), a central processing unit (CPU), a microprocessor, a microcontroller, an application processor (AP), and/or a digital signal processing core, etc., but example embodiments are not limited thereto.

The first semiconductor chip 300 may include a first substrate 310 having first and second surfaces 312 and 314 opposite to each other in the vertical direction, and a first insulating interlayer and a second insulating interlayer 320 sequentially stacked beneath the first surface 312 of the first substrate 310 in the vertical direction.

The first substrate 310 may include, for example, a semiconductor material, e.g., silicon, germanium, silicon-germanium, or a III-V group compound semiconductor, e.g., GaP, GaAs, GaSb, etc. In some example embodiments, the first substrate 310 may be or include, for example, a silicon-on-insulator (SOI) substrate or a germanium-on-insulator (GOI) substrate, but example embodiments are not limited thereto.

A circuit device, e.g., a logic device may be formed in the first insulating interlayer 320. The circuit device may include, for example, circuit patterns, e.g., transistors, capacitors, wiring structures, etc., and the wiring structures may include, e.g., wirings, vias, contact plugs, conductive pads, etc., but example embodiments are not limited thereto.

The second insulating interlayer 320 may cover or at least partially cover a sidewall of the third conductive pad 330.

The first semiconductor chip 300 may be electrically connected to the third conductive connection member 750 through the third conductive pad 330, the first conductive connection member 340, the second conductive pad 250, the redistribution wiring structure 235, the first through electrode 120, the conductive post 710 and the fifth conductive pad 740.

The second conductive connection member 440 may be disposed on and contact a corresponding one of the second conductive pads 250. The second conductive connection member 440 may include, e.g., a conductive bump and/or a conductive ball, but example embodiments are not limited thereto.

In some example embodiments, the second semiconductor chip 300 may include, for example, a volatile memory chip, e.g., a DRAM chip, an SRAM chip, etc., and/or a non-volatile memory chip, e.g., a flash memory chip, an EEPROM chip, etc., but example embodiments are not limited thereto.

The second semiconductor chip 400 may include a second substrate 410 having first and second surfaces 412 and 414 opposite to each other in the vertical direction, and a third insulating interlayer and a fourth insulating interlayer 420 sequentially stacked beneath the first surface 412 of the second substrate 410 in the vertical direction.

The second substrate 410 may include, for example, at least one semiconductor material, e.g., silicon, germanium, silicon-germanium, or a III-V group compound semiconductor, e.g., GaP, GaAs, GaSb, etc. In some example embodiments, the second substrate 410 may be or include, for example, a silicon-on-insulator (SOI) substrate and/or a germanium-on-insulator (GOI) substrate, but example embodiments are not limited thereto.

A circuit device, e.g., a memory device, may be formed in the third insulating interlayer 320. The circuit device may include, for example, circuit patterns, e.g., transistors, capacitors, wiring structures, etc., and the wiring structures may include, e.g., wirings, vias, contact plugs, conductive pads, etc., but example embodiments are not limited thereto.

The fourth insulating interlayer 420 may cover or at least partially cover a sidewall of the fourth conductive pad 430.

The second semiconductor chip 400 may be electrically connected to the third conductive connection member 750 through the fourth conductive pad 430, the second conductive connection member 440, the second conductive pad 250, the redistribution wiring structure 235, the first through electrode 120, the conductive post 710 and the fifth conductive pad 740.

FIG. 1 shows that the semiconductor package includes one second semiconductor chip 400, however, inventive concepts are not limited thereto. The semiconductor package may include, e.g., a high bandwidth memory (HBM) package having a plurality of second semiconductor chips 400, for example sequentially stacked in the vertical direction, instead of one second semiconductor chip 400.

Each of the second to fourth conductive pads 250, 330 and 430 may include, e.g., at least a metal, a metal nitride, etc., and each of the first and third insulating interlayers and the second and fourth insulating interlayers 320 and 420 may include, for example, an oxide, e.g., silicon oxide or an insulating nitride, e.g., silicon nitride, but example embodiments are not limited thereto.

The first underfill member 350 may be disposed between the first semiconductor chip 300 and the RDL 230, and may surround or at least partially surround the second conductive pad 250 and the first conductive connection member 340. The second underfill member 450 may be disposed between the second semiconductor chip 400 and the RDL 230, and may surround or at least partially surround the second conductive pad 250 and the second conductive member 440.

Any or each of the first and second underfill members 350 and 450 may include, for example, an adhesive containing, for example, epoxy, but example embodiments are not limited thereto.

The first molding member 500 may be disposed on the RDL 230, and may cover or at least partially cover sidewalls of the first and second semiconductor chips 300 and 400 and the first and third second underfill members 350 and 450. The first molding member 500 may or may not contact a sidewall of the RDL 230 and a sidewall of the interposer substrate 110. The first molding member 500 may include, for example, a polymer, e.g., EMC, but example embodiments are not limited thereto.

The semiconductor package may include the conductive post 710 and the second molding member 720 covering or at least partially covering a sidewall of the conductive post 710 under the first surface 112 of the interposer substrate 110, and the conductive post 710 may contact the first through electrode 120 extending or at least partially through the interposer substrate 110 to be electrically connected to first through electrode 120.

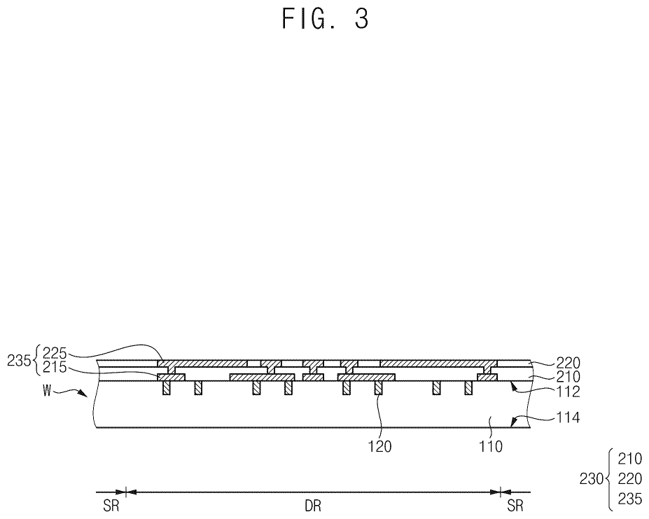

In some example embodiments, the first length L1 in the vertical direction of the first through electrode 120 may be the same as, substantially the same as, or smaller than the second length L2 in the vertical direction of the conductive post 710. As the first through electrode 120 may have the smaller length, a cost of forming the first through electrode 120 may be reduced, and as illustrated below with reference to FIGS. 3 to 11, the second molding member 720 may be formed beneath the interposer substrate 110 in addition to the first molding member 500 on the interposer substrate 110 so that warpage of the interposer substrate 110 may be reduced.

FIGS. 3 to 11 are cross-sectional views illustrating a method of manufacturing a semiconductor package in accordance with some example embodiments.

Referring to FIG. 3, a wafer W for forming a plurality of interposers is provided. In some example embodiments, the wafer W may include an interposer substrate 110 having first and second surfaces 112 and 114 opposite to each other in the vertical direction, and the interposer substrate 110 may include, for example, a semiconductor material such as, for example, silicon, germanium, silicon-germanium, etc., or glass, but example embodiments are not limited thereto. In some example embodiments, the interposer substrate 110 may have a thickness of, for example, about 600 μm to about 800 μm in the vertical direction, but example embodiments are not limited thereto.

Additionally, the wafer W may include a plurality of die regions DR and a scribe lane region SR surrounding the die region DR, and the wafer W may be cut by a sawing process along the scribe lane region SR to be singulated into a plurality of interposers in respective die regions DR.

In a die region DR, a plurality of first through electrodes 120, each of which may extend or at least partially extend in the vertical direction through an upper portion of the interposer substrate 110, for example, a portion of the interposer substrate 110 adjacent to the first surface 112, and may be spaced apart from each other in the horizontal direction. In some example embodiments, each of the first through electrodes 120 may have a length of, for example, about 30 μm to about 50 μm in the vertical direction, but example embodiments are not limited thereto.

An RDL 230 may be formed on the first surface 112 of the interposer substrate 110. In some example embodiments, the RDL 230 may include, for example, insulation layers, which may be stacked in the vertical direction, and a redistribution wiring structure, for example in (for example, surrounded or at least partially surrounded by), one or more of the insulation layers, and the redistribution wiring structure may include, e.g., redistribution wirings, vias, contact plugs and/or conductive pads, but example embodiments are not limited thereto.

FIG. 3 shows that the RDL 230 includes first and second insulation layers 210 and 220 sequentially stacked in the vertical direction, and the redistribution wiring structure 235 includes a first conductive pad 215 and a redistribution wiring 225 sequentially stacked in the vertical direction, but inventive concepts are not limited thereto. For example, the RDL 230 may include more than two insulation layers, and the redistribution wiring structure 235 may include redistribution wirings, vias, contact plugs, conductive pads, etc., having various horizontal and vertical layouts in (for example, surrounded or at least partially surround by) one or more of the insulation layers.

For example, the RDL 230 may be formed on the interposer substrate 110 as follows.

A first conductive pad layer may be formed on the first surface 112 of the interposer substrate 110 and on the first through electrode 120, the first conductive pad layer may be patterned to form a first conductive pad 215 contacting an upper surface of the first through electrode 120, a first insulation layer 210 may be formed on the interposer substrate 110 and on the first through electrode 120 to cover or at least partially cover the first conductive pad 215, and the first insulation layer 210 may be partially removed as to form (for example, define or at least partially define) a first opening exposing or at least partially exposing an upper surface of the first conductive pad 215.

A seed layer may be formed on an upper surface of the first insulation layer, a sidewall of (for example, defining or at least partially defining) the first opening and the upper surface of the first conductive pad 215 exposed by the first opening. For example, an electroplating process or an electroless plating process may be performed to form a redistribution wiring layer on the seed layer, the redistribution wiring layer may be patterned to form a redistribution wiring 225, and a portion of the seed layer not covered by the redistribution wiring 225 may be removed or at least partially removed. The redistribution wiring 225 may contact an upper surface of the first conductive pad 215 through (for example, within) the first opening.

A second insulation layer 220 may be formed on the first insulation layer 210 to cover or at least partially cover the redistribution wiring 225, and a planarization process may be performed on the second insulation layer 220 until an upper surface of the second redistribution wiring 225 is exposed, so that the second insulation layer 220 may cover or at least partially cover a sidewall of the redistribution wiring 225. The planarization process may include, e.g., a chemical mechanical polishing (CMP) process, but example embodiments are not limited thereto.

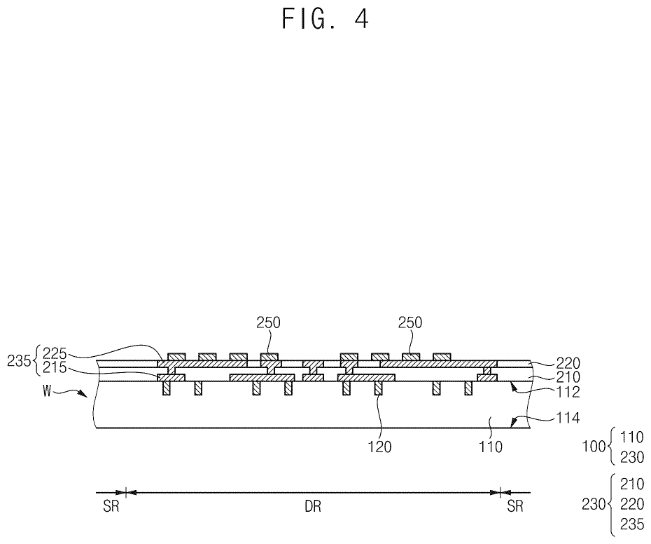

Referring to FIG. 4, a second conductive pad 250 may be formed to contact an upper surface of the redistribution wiring 225.

The second conductive pad 250 may be formed by forming a second conductive pad layer on the RDL 230 including the redistribution wiring structure 235 and patterning the second conductive pad layer. In some example embodiments, a plurality of second conductive pads 250 may be formed to be spaced apart from each other in the horizontal direction.

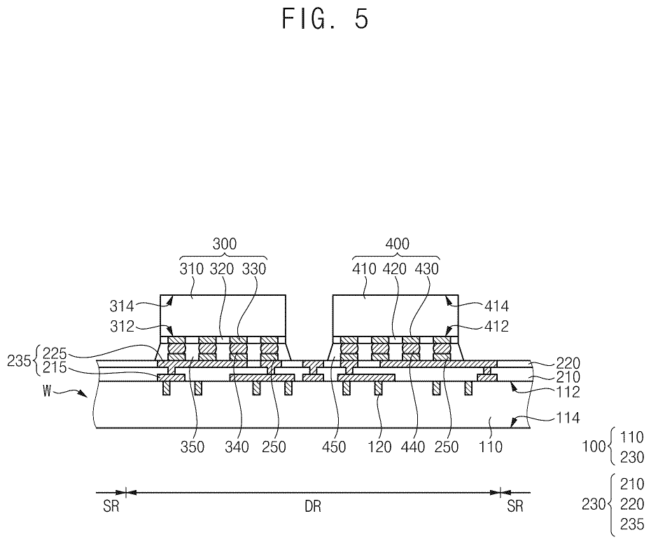

Referring to FIG. 5, first and second semiconductor chips 300 and 400 may be mounted on and/or bonded with the RDL 230 by, for example, a thermal compression bonding (TCB) process.

However, inventive concepts are not limited thereto, and for example, the first chip 300 and/or second semiconductor chips 400 may be bonded with (for example, to) the RDL 230 by, e.g., a hybrid copper bonding (HCB) or other process.

In some example embodiments, the first semiconductor chip 300 may include a first substrate 310 having first and second surfaces 312 and 314 opposite to each other in the vertical direction, and a first insulating interlayer and a second insulating interlayer 320 sequentially stacked in the vertical direction, and a third conductive pad 330 may be formed in the second insulating interlayer 320.

A first conductive connection member 340 may be formed on the third conductive pad 330, the first semiconductor chip 300 may be flipped such that the first surface 312 of the first semiconductor chip 300 may face downwardly, and the first semiconductor chip 300 may be mounted on the RDL 230 such that the first conductive connection member 340 may contact an upper surface of the second conductive pad 250.

A thermal compression process, for example, may be performed at a temperature equal to or less than about 400° C., such that the first semiconductor chip 300 may be bonded to an upper surface of the second conductive pad 250 on the RDL 230. A first underfill member 350 may be formed between the RDL 230 and the first semiconductor chip 300 to cover or at least partially cover the second conductive pad 250 and the first conductive connection member 340.

In some example embodiments, the second semiconductor chip 400 may include a first substrate 410 having first and second surfaces 412 and 414 opposite to each other in the vertical direction, and a third insulating interlayer and a fourth insulating interlayer 420 sequentially stacked in the vertical direction, and a fourth conductive pad 430 may be formed in the fourth insulating interlayer 420.

A second conductive connection member 440 may be formed on the fourth conductive pad 430, the second semiconductor chip 400 may be flipped such that the first surface 412 of the second semiconductor chip 400 may face downwardly, and the second semiconductor chip 400 may be mounted on the RDL 230 such that the second conductive connection member 440 may contact an upper surface of the second conductive pad 250.

A thermal compression process, for example, may be performed at a temperature equal to or less than about 400° C. so that the second semiconductor chip 400 may be bonded to an upper surface of the second conductive pad 250 on the RDL 230. A second underfill member 450 may be formed between the RDL 230 and the second semiconductor chip 400 to cover or at least partially cover the second conductive pad 250 and the second conductive connection member 440.

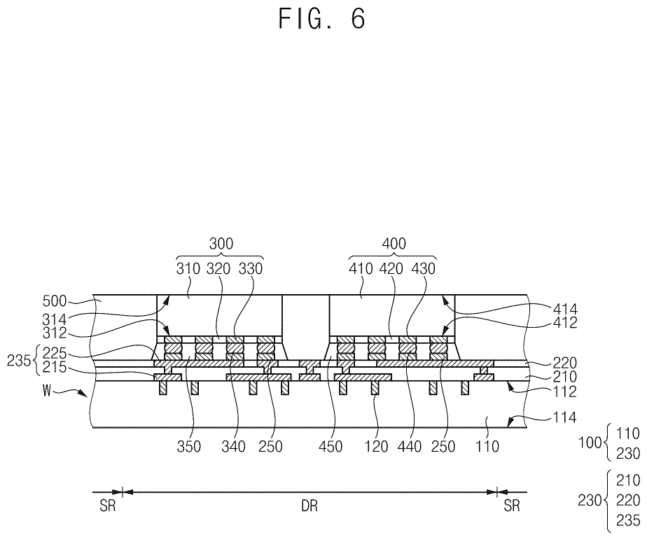

Referring to FIG. 6, a first molding member 500 may be formed on the RDL 230 including the redistribution wiring structure 235 to cover or at least partially cover the first and second semiconductor chips 300 and 400 and/or the first and second underfill members 350 and 450, and, for example, a planarization process may be performed until upper surfaces of the first and second semiconductor chips 300 and 400 are exposed or at least partially exposed.

In some example embodiments, the planarization process may include, for example, a grinding process. As the planarization process is performed, an upper surface of the first molding member 500 may be coplanar or substantially coplanar with the upper surfaces of the first semiconductor chip 300 and/or second semiconductor chips 400, and the first molding member 500 may cover or at least partially cover sidewalls of the first and second semiconductor chips 300 and 400 and/or of the first and second underfill members 350 and 450.

The first molding member 500 may include, for example, a polymer, e.g., EMC. For example, the polymer may have a coefficient of thermal expansion (CTE) different from that of interposer substrate 110 including, e.g., a semiconductor material such as, for example, silicon, and accordingly, as the first molding member 500 is formed on the wafer W, in the conventional art warpage may occur in the interposer substrate 110.

However, in some example embodiments according to inventive concepts, the interposer substrate 110 may have a relatively large thickness of about 600 μm to about 800 μm, and the thickness may not be reduced by a grinding process, such that the warpage of the interposer substrate 110 may not be relatively large and/or substantial even though the first molding member 500 having the CTE different from that of the interposer substrate 110 may be formed on the wafer W.

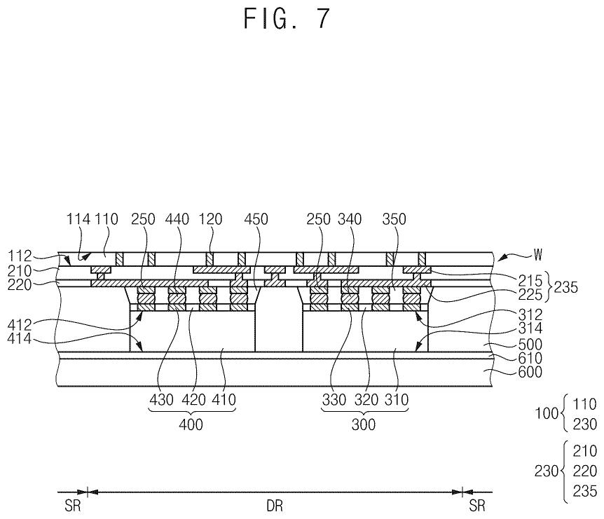

Referring to FIG. 7, a temporary adhesion layer 610 may be attached to a carrier substrate 600, the first carrier substrate 600 may be bonded with the wafer W such that the temporary adhesion layer 610 may contact the upper surface of the first semiconductor chip 300 and/or of the second semiconductor chips 400 and/or an upper surface of the first molding member 500, and the wafer W may be flipped.

The carrier substrate 600 may include, e.g., a metal or non-metal plate, a silicon substrate, and/or a glass substrate, etc., but example embodiments are not limited thereto. The temporary adhesion layer 610 may include, for example, a material that may lose adhesion by irradiation of light or heat treatment. But example embodiments are not limited thereto. In some example embodiments, the temporary adhesion layer 610 may include, for example, glue.

A portion of the interposer substrate 110 adjacent to the second surface 114 may be removed or at least partially removed by, e.g., a grinding process to expose or at least partially expose an upper surface of the first through electrode 120.

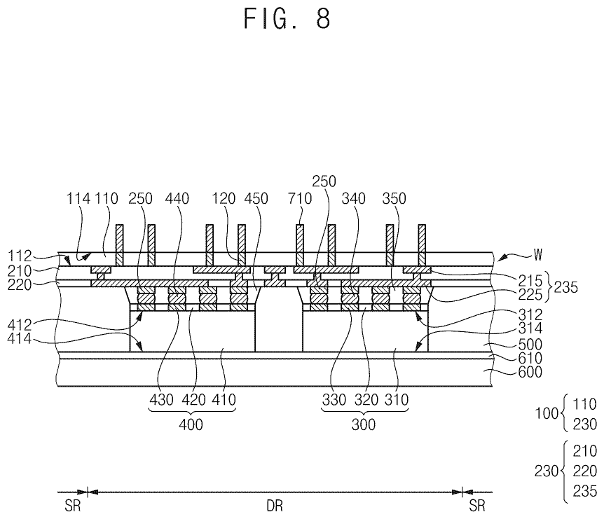

Referring to FIG. 8, a photoresist layer may be formed on the second surface 114 of the interposer substrate 110, and an exposure process and a developing process may be performed to form a photoresist pattern having a second opening exposing the upper surface of the first through electrode 120, and for example, an electroplating process may be performed to form a conductive post 710 in the second opening.

In some example embodiment, the conductive post 710 may have a length of about 50 μm to about 70 μm in the vertical direction, but example embodiments are not limited thereto.

The photoresist pattern may be removed by, e.g., an ashing process and/or a stripping process, but example embodiments are not limited thereto.

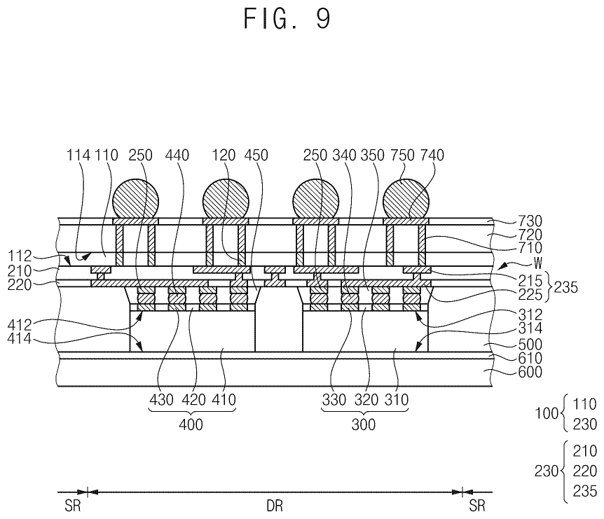

Referring to FIG. 9, a second molding member 720 may be formed on the second surface 114 of the interposer substrate 110 to cover or at least partially cover the conductive post 710, and a planarization process may be performed until an upper surface of the conductive post 710 is exposed (for example, at least partially exposed).

In some example embodiments, the planarization process may include, for example, a grinding process. By the planarization process, an upper surface of the second molding member 720 may be coplanar or substantially coplanar with the upper surface of the conductive post 710, and the second molding member 720 may cover or at least partially cover a sidewall of the conductive post 710.

In some example embodiments, the second molding member 720 may include a same or substantially the same material as that of the first molding member 500, and may include, for example, a polymer, e.g., EMC. The second molding member 720 may have, for example, a CTE different from that of the interposer substrate 110 which may include, e.g., silicon, and as the first and second molding members 500 and 720 including the material having the same or substantially the same CTE may be formed beneath the first surface 112 and on the second surface 114, respectively, of the interposer substrate 110, pressures from the first and second molding members 500 and 720 exerted onto the interposer substrate 110 may be offset such that the warpage of the interposer substrate 110 may be reduced (for example, relatively reduced and/or substantially reduced).

A fifth conductive pad 740 and a third insulation layer 730 covering or at least partially covering a sidewall of the fifth conductive pad 740 may be formed on the second molding member 720 and the conductive post 710. The fifth conductive pad 740 may contact the upper surface of the conductive post 710. Alternatively, or additionally, an RDL including a redistribution wiring structure may be formed on the second molding member 720 and the conductive post 710.

A third conductive connection member 750 may be formed to contact an upper surface of the fifth conductive pad 740.

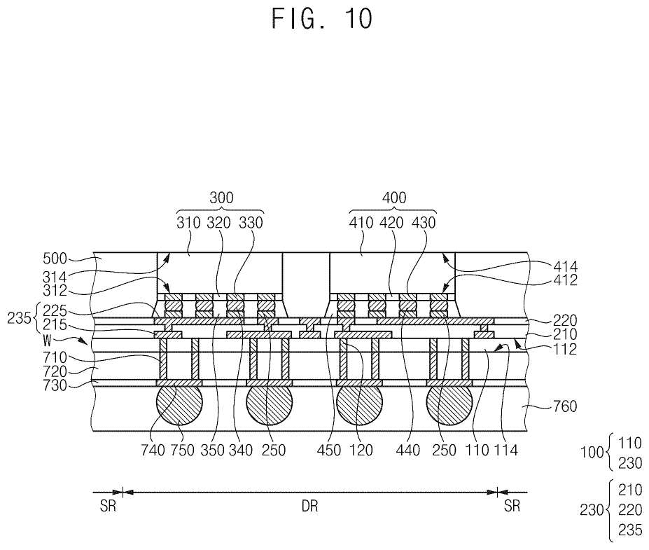

Referring to FIG. 10, a fourth insulation layer 760 may be formed on the third insulation layer 730 to cover or at least partially cover the third conductive connection member 750, and the temporary adhesion layer 610 may be separated from the first molding member 500 and the first and second semiconductor chips 300 and 400 such that the carrier substrate 600 may be separated from the wafer W, and accordingly the upper surfaces of the first molding member 500 and the first and second semiconductor chips 300 and 400 may be exposed (for example, at least partially exposed).

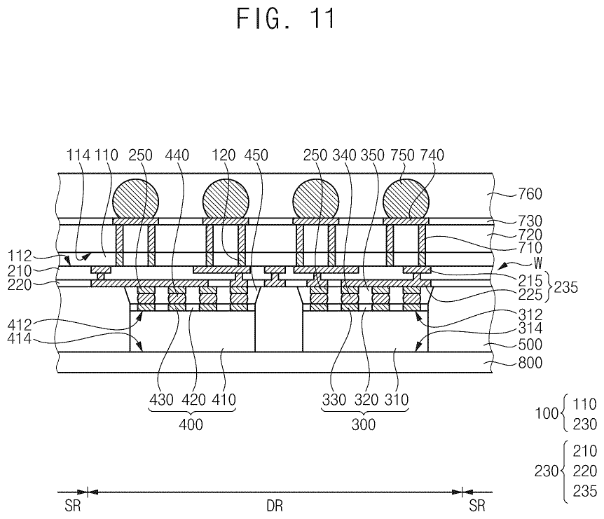

Referring to FIG. 11, the wafer W may be flipped, and may be bonded to an upper surface of a dicing film 800 on a frame having, e.g., a ring shape, but example embodiments are not limited thereto.

The dicing film 800 may contact an upper surface of the first molding member 500 and/or of the first semiconductor chip 300 and/or second semiconductor chip 400.

Referring to FIG. 1 again, the wafer W may be cut along the scribe lane region SR by, e.g., a sawing process such as to be singulated into a plurality of interposers 100.

During the sawing process, the second molding member 720 and the third and fourth insulation layers 730 and 760 stacked in the vertical direction on the wafer W, and the first molding member 500 and the dicing film 800 stacked in the vertical direction beneath the wafer W may also be cut to be stacked on and beneath each of the singulated interposers 100.

Each of the interposers 100 may be separated from the dicing film 800, and the fourth insulation layer 760 may be removed to complete the manufacturing the semiconductor package.

As illustrated above, the first through electrode 120 extending or at least partially extending through the upper portion of the interposer substrate 110 included in the wafer W1 may be formed, the RDL 230 may be formed on the first surface 112 of the interposer substrate 110, the first and second semiconductor chips 300 and 400 may be bonded to the RDL 230, the first molding member 500 may be formed to cover or at least partially cover the sidewalls of the first semiconductor chip 300 and/or second semiconductor chips 400, the carrier substrate 600 may be bonded to the upper surfaces of the first molding member 500 and/or the first and second semiconductor chips 300 and 400, the carrier substrate 600 may be flipped, the upper portion of the interposer substrate 110 may be removed to expose the upper surface of the first through electrode 120, the conductive post 710 may be formed to contact the upper surface of the first through electrode 120, the second molding member 720 may be formed to cover or at least partially the sidewall of the conductive post 710, the third conductive connection member 750 may be formed to be electrically connected to the conductive post 710, and the wafer W1 may be singulated into the interposers 100 by, for example, the sawing process, such that the semiconductor package including each of the interposers 100 and the stack structures on and beneath each of the interposers 100 may be manufactured.

In some example embodiments, the length in the vertical direction of the first through electrode 120 may be much (for example, substantially) less than that of the interposer substrate 110, and accordingly, after the grinding process for exposing the upper surface of the first through electrode 120, the interposer substrate 110 may have a very (for example, relatively) small thickness in the vertical direction.

However, before the grinding process on the interposer substrate 110, the first and second semiconductor chips 300 and 400 may be stacked on the wafer W, and thus, even though the first molding member 500 including the material having a CTE different from that of the interposer substrate 110 is formed on the wafer W, the interposer substrate 110 may have a relatively large thickness so that the warpage of the interposer substrate 110 by the first molding member 500 may not be so great, and that an additional carrier substrate in consideration of the warpage of the interposer substrate 110 may not be required and/or advantageous.

Additionally, the second molding member 720 covering or at least partially covering the sidewall of the conductive post 710 on the second surface 114 of the interposer substrate 110 in which the first through electrode 120 is formed may include the same or substantially the same material as that of the first molding member 500, and thus may apply a pressure having a magnitude the same as, substantially the same as, or similar to a magnitude of the first molding member 500 in a direction that may offset the pressure of the first molding member 500, such that the warpage of the interposer substrate 110 may be reduced.

As the first through electrode 120 in the interposer substrate 110 may have a length in the vertical direction that is very (for example, relatively) small, cost of the process for forming the first through electrode 120 in the interposer substrate 110 may be reduced.

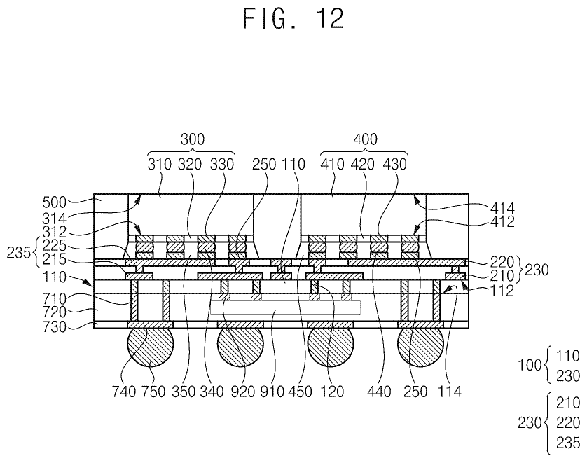

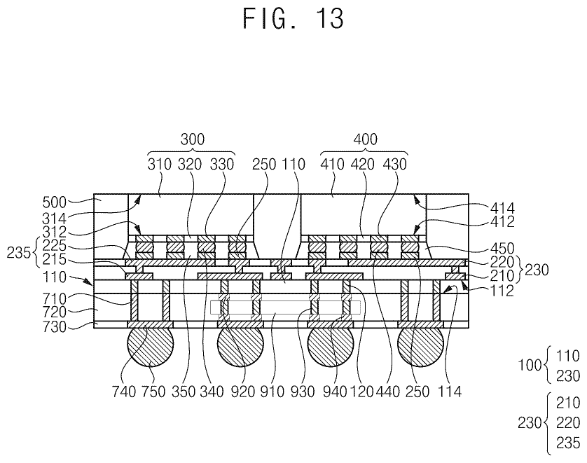

FIGS. 12 and 13 are cross-sectional views respectively illustrating semiconductor packages in accordance with some example embodiments. These semiconductor packages may be the same as, substantially the same as, or similar to that of FIGS. 1 and 2, except for one or more elements. Thus, repeated or redundant explanations are omitted herein.

Referring to FIG. 12, the semiconductor package may further include a third semiconductor chip 910, which may be disposed under the interposer substrate 110 and be covered or at least partially covered by the second molding member 720, and/or a sixth conductive pad 920 contacting the first through electrode 120 and/or the third semiconductor chip 910.

In some example embodiments, the third semiconductor chip 910 may be or include, for example, a logic chip and/or a memory chip. Alternatively, the third semiconductor chip 910 may be or include a dummy chip serving (for example, configured to serve) as a bridge between neighboring (for example, adjacent) ones of first through electrodes 120.

In some example embodiments, the third semiconductor chip 910 may overlap at least partially any or each of the first and second semiconductor chips 300 and 400 in the vertical direction.

In some example embodiments, the third semiconductor chip 910 may have a length in the vertical direction that is smaller than that of the conductive post 710, but example embodiments are not limited thereto.

In some example embodiments, the conductive posts 710 contacting the first through electrodes 120, respectively, and the second molding member 720 covering or at least partially covering the conductive posts 710, may be disposed beneath the interposer substrate 110.

In the semiconductor package, the interposer substrate 110 may not have a relatively large thickness in the vertical direction and each of the first through electrodes 120 may have a relatively large length in the vertical direction. Instead, in the semiconductor package, the interposer substrate 110 may have a relatively small thickness in the vertical direction and each of the first through electrodes 120 may have a relatively small length in the vertical direction. The semiconductor package may include the conductive posts 710 contacting the first through electrodes 120, respectively, and the second molding member 720 covering the conductive posts 710.

Accordingly, the third semiconductor chip 910 may be formed in a space between (for example, horizontally between) ones of conductive posts 710 spaced apart from each other in the horizontal direction, and the semiconductor package including the third semiconductor chip 910 may have enhanced electric characteristics.

Referring to FIG. 13, the semiconductor package may further include a second through electrode 930 extending or at least partially extending through the third semiconductor chip 910 shown in FIG. 12, and a seventh conductive pad 940 contacting the second through electrode 930 and the fifth conductive pad 740.

Accordingly, the third semiconductor chip 910 may be electrically connected to the first through electrode 120 via the sixth conductive pad 920, and may also be electrically connected to the third conductive connection member 750 via the seventh conductive pad 940.

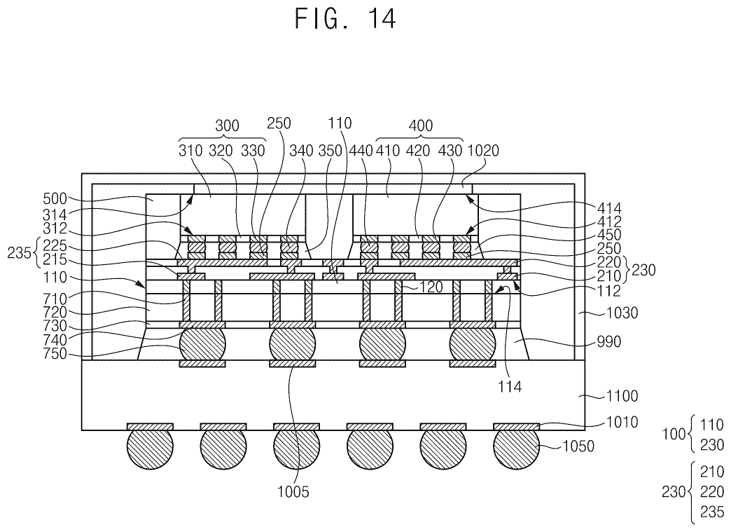

FIG. 14 is a cross-sectional view illustrating a semiconductor module in accordance with some example embodiments.

This semiconductor module may include the semiconductor package of FIGS. 1 and 2, and thus repeated explanations are omitted herein.

Referring to FIG. 14, the semiconductor module may further include, for example, a package substrate 1000, a fourth conductive connection member 1050, a heat slug 1030 and a heat emission member 1020, and eighth and ninth conductive pads 1005 and 1010 may be disposed in the package substrate 1000.

In some example embodiments, the package substrate 1000 may have upper and lower surfaces opposite to each other in the vertical direction, and may be or include, e.g., a PCB, but example embodiments are not limited thereto. The PCB may include, for example, various types of circuit patterns therein, but example embodiments are not limited thereto.

The eighth and ninth conductive pads 1005 and 1010 may be disposed in upper and lower portions, respectively, of the package substrate 1000, and may contact the third and fourth conductive connection members 750 and 1050, respectively. Such a semiconductor module may be, for example, mounted on a module substrate via the fourth conductive connection member 1050 beneath a lower surface of the package substrate 1000, but example embodiments are not limited thereto.

In some example embodiments, the heat slug 1030 may thermally contact (for example, be in thermal contact with) and/or cover or at least partially cover the first and second semiconductor chips 300 and 400 and/or the first molding member 500 on the package substrate 1000. The heat emission member 1020 may be disposed, for example, on upper surfaces of the first and second semiconductor chips 300 and 400 and/or the first molding member 500, and may include, e.g., a thermal interface material (TIM), but example embodiments are not limited thereto. The heat slug 1030 may, for example, thermally contact the first and second semiconductor chips 300 and 400 via the heat emission member 1020, but example embodiments are not limited thereto.

The foregoing is illustrative of some example embodiments and is not to be construed as limiting thereof. Although a few example embodiments have been described, those ordinarily skilled in the art will readily appreciate that many modifications are possible in example embodiments without materially departing from the novel teachings and advantages of the present inventive concepts. Accordingly, all such modifications are intended to be included within the spirit and scope of example embodiments as in the claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package, comprising:
an interposer substrate having first and second surfaces opposite to each other in a vertical direction;
a through electrode at least partially extending through the interposer substrate;
a redistribution layer (RDL) on the first surface of the interposer substrate and on an upper surface of the through electrode, the RDL including a redistribution wiring structure;
first and second semiconductor chips on the RDL and spaced apart from each other in a horizontal direction, each of the first and second semiconductor chips being electrically connected to the redistribution wiring structure;
a first molding member on the RDL and at least partially covering a sidewall of the first semiconductor chip and a sidewall of second semiconductor chip;
a conductive post on the second surface of the interposer substrate and contacting the through electrode; and
a second molding member on the second surface of the interposer substrate and at least partially covering a sidewall of the conductive post,
wherein a maximum width in the horizontal direction of the through electrode is equal to or greater than a width in the horizontal direction of the conductive post, and
wherein a length in the vertical direction of the through electrode is equal to or less than a length in the vertical direction of the conductive post.

2. The semiconductor package according to claim 1, wherein the length in the vertical direction of the conductive post is 1 to 2.5 times the length in the vertical direction of the through electrode.

3. The semiconductor package according to claim 1, wherein a cross-section of a sidewall of the through electrode has a scalloped shape.

4. The semiconductor package according to claim 1, wherein a sidewall of the conductive post is flat.

5. The semiconductor package according to claim 1, wherein the first and second molding members include a same material.

6. The semiconductor package according to claim 5, wherein the interposer substrate includes silicon, and the first and second molding members each include an epoxy molding compound (EMC).

7. The semiconductor package according to claim 1, further comprising a third semiconductor chip under the second surface of the interposer substrate, the third semiconductor chip being spaced apart from the conductive post in the horizontal direction.

8. The semiconductor package according to claim 7, wherein the third semiconductor chip at least partially overlaps with each of the first and second semiconductor chips in the vertical direction.

9. The semiconductor package according to claim 7, wherein a thickness in the vertical direction of the third semiconductor chip is less than the length in the vertical direction of the conductive post.

10. The semiconductor package according to claim 1, wherein the first semiconductor chip includes an application specific integrated circuit (ASIC), and the second semiconductor chip includes a memory chip.

11. A semiconductor package comprising:
an interposer substrate having first and second surfaces opposite to each other in a vertical direction;
a through electrode at least partially extending through the interposer substrate;
a redistribution layer (RDL) on the first surface of the interposer substrate and on an upper surface of the through electrode, the RDL including a redistribution wiring structure;
first and second semiconductor chips spaced apart from each other in a horizontal direction on the RDL, each of the first and second semiconductor chips being electrically connected to the redistribution wiring structure;
a first molding member on the RDL and at least partially covering a sidewall of the first semiconductor chip and a sidewall of the second semiconductor chip;
a conductive post on the second surface of the interposer substrate and contacting the through electrode;
a third semiconductor chip spaced apart from the conductive post in the horizontal direction and under the second surface of the interposer substrate, the third semiconductor chip at least partially overlapping with each of the first and second semiconductor chips in the vertical direction; and
a second molding member on the second surface of the interposer substrate and at least partially covering a sidewall of the conductive post and the third semiconductor chip.

12. The semiconductor package according to claim 11, wherein the first molding member does not contact at least one sidewall of the interposer substrate.

13. The semiconductor package according to claim 11, wherein the third semiconductor chip includes at least one of a logic chip or a memory chip.

14. The semiconductor package according to claim 11, wherein a thickness in the vertical direction of the third semiconductor chip is less than a length in the vertical direction of the conductive post.

15. The semiconductor package according to claim 11, further comprising a plurality of through electrodes spaced apart from each other in the horizontal direction,
wherein the third semiconductor chip is a dummy chip configured to serve as a bridge between the plurality of through electrodes.

16. The semiconductor package according to claim 11, wherein a length in the vertical direction of the conductive post is equal to or greater than a length in the vertical direction of the through electrode.

17. The semiconductor package according to claim 11, wherein a width in the horizontal direction of the conductive post is equal to or less than a maximum width in the horizontal direction of the through electrode.

18. The semiconductor package according to claim 11, wherein a profile of a sidewall of the through electrode is different from a profile of a sidewall of the conductive post such that the through electrode is differentiated from the conductive post.

19. A semiconductor package, comprising:
an interposer substrate having first and second surfaces opposite to each other in a vertical direction;
through electrodes spaced apart from each other in a horizontal direction, each of the through electrodes at least partially extending through the interposer substrate;
a redistribution layer (RDL) on the first surface of the interposer substrate and on upper surfaces of the through electrodes, the RDL including a redistribution wiring structure;
conductive pads on the RDL and spaced apart from each other in the horizontal direction;
a first conductive connection member contacting an upper surface of a first conductive pad among the conductive pads;
a first semiconductor chip on and electrically connected to the first conductive connection member;
a first underfill member between the RDL and the first semiconductor chip and at least partially covering the first conductive pad and the first conductive connection member;
a second conductive connection member contacting an upper surface of a second conductive pad among the conductive pads;
a second semiconductor chip on and electronically connected to the second conductive connection member;
a second underfill member between the RDL and the second semiconductor chip and at least partially covering the second conductive pad and the second conductive connection member;
a first molding member on the RDL and at least partially covering
a sidewall of the first semiconductor chip,
a sidewall of the second semiconductor chip,
a sidewall of the first underfill member, and
a sidewall of the second underfill member;
conductive posts on the second surface of the interposer substrate and contacting the through electrodes, respectively; and
a second molding member on the second surface of the interposer substrate and at least partially covering a sidewall of the conductive posts,
wherein a maximum width in the horizontal direction of each of the through electrodes is equal to or greater than a width in the horizontal direction of a corresponding one of the conductive posts.

20. The semiconductor package according to claim 19, further comprising a third semiconductor chip under the second surface of the interposer substrate, the third semiconductor chip being spaced apart from the conductive posts in the horizontal direction and at least partially overlapping with each of the first and second semiconductor chips in the vertical direction.
